(19) United States
(12) Patent Application Publication
(10) Pub. No.: US 2007/0131448 A1
(43) Pub. Date: Jun. 14, 2007

(54) Circuit board structure with heat radiating layer

(75) Inventor: Yu Li Huang, Taoyuan Hsien (TW)

Correspondence Address: TROXELL LAW OFFICE PLLC, SUITE 1404, 5205 LEESBURG PIKE, FALLS CHURCH, VA, 22041, US

(73) Assignee: INSIGHT ELECTRONIC GROUP INC.

(21) Appl. No.: 11/593,632

(22) Filed: Nov. 7, 2006

(30) Foreign Application Priority Data
Dec. 9, 2005 (TW) 94221529

(51) Int. Cl. H05K 1/00; H05K 7/20

(52) U.S. Cl. 174/252; 361/708

(57) ABSTRACT

A circuit board structure includes a heat radiating layer that is integrally pressed to bond to a copper foil layer or a substrate for a circuit board and then machined to form a plurality of erect fins or a specific three-dimensional surface profile, so as to provide the circuit board structure with increased heat dissipating surface area. When electronic elements mounted on the circuit board structure produce heat during operation thereof, the produced heat is quickly transferred from the copper foil layer to the heat radiating layer. With the fins and the large heat dissipating area provided by the heat radiating layer, heat transferred to the heat radiating layer may be highly efficiently dissipated into air.

### FIELD OF THE INVENTION

The present invention relates to a circuit board structure with heat radiating layer, and more particularly to a circuit board structure having a heat radiating layer that is integrally pressed to bond to a copper foil layer or a substrate of a circuit board, and then machined to form a plurality of fins to largely increase the heat dissipating surface area of the circuit board, so that heat produced by electronic elements on the circuit board may be quickly transferred to and dissipated from the heat radiating layer.

### BACKGROUND OF THE INVENTION

Circuit boards have wide applications in different fields. Electronic elements in most electronic products are mounted on a circuit board. Some of these electronic elements are high-power elements to produce high amount of heat during operation thereof. Therefore, currently available circuit boards are usually enhanced in design to enable quick heat dissipation therefrom.

In the past, since only a small number of low power consumption electronic elements are mounted on a conventional circuit board, most of the heat produced by the electronic elements during operation is transmitted to a copper foil layer on the circuit board and dissipated into air therefrom. However, the nowadays circuit boards have a large number of high-power electronic elements mounted thereon. With the increased current supplied to the electronic elements, the power consumed by the electronic elements is increased at the same time to result in very high temperature at some areas on the circuit boards. The high amount of heat produced by the large quantity of high-power electronic elements on a circuit board could not be completely radiated simply via conductive contact pins provided on the electronic elements, and the circuit board and the electronic elements fail to maintain at normal operating temperatures. Exceeded operating temperatures would result in changes in the physical properties of the electronic elements to adversely affect the working performance, and risks of burnout and shortened service life of the electronic elements.

The currently available circuit boards, either single-layer or multilayer circuit boards, do not include any heat radiating structure. When an electronic element that would produce high amount of heat, such as a central processing unit or a North Bridge chipset, is mounted on a circuit board, a metal radiating sheet, preferably made of aluminum or copper, has to be added to the electronic element while using a thermal paste or a thermal tape as a conductive medium. Due to the metal property of the heat radiating sheets, the heat produced by the electronic elements may be quickly transmitted to and dissipated from the heat radiating sheets, so that the circuit board and the electronic elements may be effectively maintained at their normal operating temperatures.

There is a commercially available aluminum substrate with pretty good heat dissipation effect and suitable for use with heat-producing electronic elements. The aluminum substrate includes a copper foil layer, an aluminum sheet, and an adhesive sheet located between the copper foil layer and the aluminum sheet. When the three layers are compressed and laminated, the adhesive sheet is firmly connected to the copper foil layer and the aluminum sheet to form the aluminum substrate. When the electronic elements mounted on the aluminum substrate produce heat, the produced heat is transmitted to the aluminum sheet via the copper foil layer. The metal property of the aluminum sheet allows the heat transmitted thereto to dissipate into air.

However, either the conventional circuit board or the above-described aluminum substrate has many disadvantages in terms of the manufacture and use thereof:
1. While the metal heat radiating sheets are added to the electronic elements on the conventional circuit board in an attempt to enhance the dissipation of the produced heat, these metal heat radiating sheets also increase the overall manufacturing cost of the circuit board. Moreover, these metal radiating sheets have a large volume to cause inconveniences in assembling them to the circuit board, and there might not be enough space on the circuit board to accommodate these metal radiating sheets.
2. The heat radiating effect of the aluminum sheet is determined by its thickness. The conventional aluminum substrate usually has an overall thickness of 1.6 mm, which is too small to effectively remove the heat produced by the electronic elements and chipsets from the circuit board.

It is therefore an important issue in the electronic industry to develop a circuit board having even better heat dissipating ability.

### SUMMARY OF THE INVENTION

A primary object of the present invention is to provide a circuit board structure with heat radiating layer. The heat radiating layer is integrally pressed to bond to a copper foil layer on a circuit board and then machined to form a plurality of erect fins or a specific three-dimensional surface profile, so as to provide the circuit board with increased heat dissipating surface area.

Another object of the present invention is to provide a circuit board structure with heat radiating layer. The heat radiating layer is machined to form a plurality of erect fins or a specific three-dimensional surface profile, so as to transform from a planar into a three-dimensional heat radiating layer with increased heat dissipating surface area.

A further object of the present invention is to provide a circuit board structure with a three-dimensional heat radiating layer, which has increased heat dissipating surface area to enable heat produced by electronic elements to be effectively carried away from a circuit board.

A still further object of the present invention is to provide a circuit board structure with a heat radiating layer integrally provided on a circuit board, so that it is not necessary to add separate heat radiating sheets to individual electronic elements on the circuit board to save time and labor costs in manufacturing the circuit board.

To achieve the above and other objects, the circuit board structure according to the present invention includes a heat radiating layer and a copper foil layer, and a layer of thermal adhesive applied between the heating radiating layer and the copper foil layer, so that the heating radiating layer and the copper foil layer may be pressed to bond together via the thermal adhesive layer. The heating radiating layer is then machined to form a plurality of erect and three-dimensional fins to provide increased heat dissipating surface area.

In an operable embodiment, the heat radiating layer is made of an aluminum material or other suitable metal materials.

In a most preferable embodiment, the heat radiating layer is pressed to bond to an aluminum substrate, so as to obtain an even better heat radiating effect.

In another embodiment, the heat radiating layer is directly laminated to a circuit board, which may be a single-layer or a multilayer circuit board.

When the electronic elements mounted on the circuit board structure produce a large amount of heat during operation thereof, the produced heat is quickly transferred from the copper foil layer to the heat radiating layer. With the three-dimensional fins and the large heat dissipating area provided by the heat radiating layer, heat produced by the electronic elements and transferred to the heat radiating layer may be highly efficiently dissipated into air. Therefore, the circuit board structure of the present invention has improved overall heat radiating efficiency to ensure that the electronic elements the circuit board work at normal operating temperatures without becoming overheated, and can therefore have extended service life. Moreover, since it is not necessary to add separate heat radiating sheets to individual electronic elements, the circuit board structure may be produced at reduced time and labor costs.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a sectioned side view of a circuit board structure with heat radiating layer according to a first embodiment of the present invention;

FIG. 2 is an exploded view of FIG. 1;

FIG. 3 shows the heat radiating layer on the circuit board structure of FIG. 1 is machined to form a plurality of fins;

FIG. 4 shows how the circuit board structure of FIG. 3 transfers heat;

FIG. 5 is a sectioned side view of a circuit board structure with heat radiating layer according to a second embodiment of the present invention;

FIG. 6 shows how the circuit board structure of FIG. 5 transfers heat;

FIG. 7 is a sectioned side view of a circuit board structure with heat radiating layer according to a third embodiment of the present invention;

FIG. 8 shows how the circuit board structure of FIG. 7 transfers heat;

FIG. 9 shows another embodiment of the circuit board structure of FIG. 8;

FIG. 10 is a sectioned side view of a circuit board structure with heat radiating layer according to a fourth embodiment of the present invention;

FIG. 11 shows how the circuit board structure of FIG. 10 transfers heat; and

FIG. 12 shows another embodiment of the circuit board structure of FIG. 11.

### DETAILED DESCRIPTION OF THE PREFERRED EMBODIMENTS

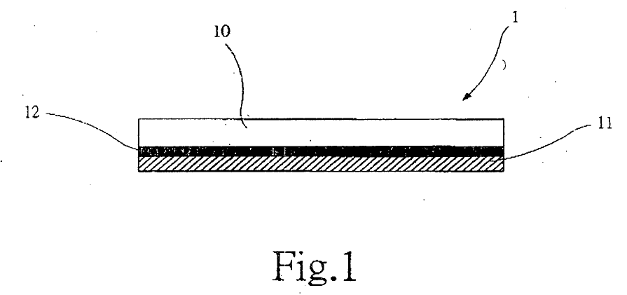

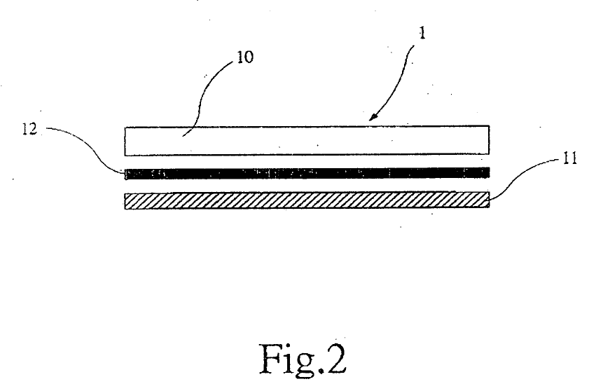

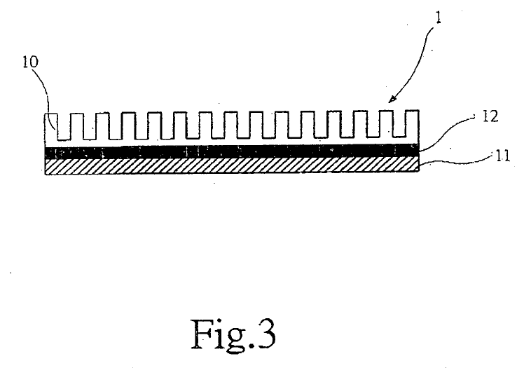

Please refer to FIGS. 1 and 2 that are assembled and exploded sectioned side views, respectively, of a circuit board structure with heat radiating layer according to a first embodiment of the present invention. As shown, the circuit board structure 1 includes a heat radiating layer 10 and a copper foil layer 11, and is characterized in that a layer of thermal adhesive 12 is applied between the heat radiating layer 10 and the copper foil layer 11, and that, after the layers 10, 11, and 12 are pressed to bond together, the heat radiating layer 10 is machined to form a plurality of erect and three-dimensional fins and accordingly provides a largely increased radiating surface area, as shown in FIG. 3.

In an operable embodiment of the present invention, the heat radiating layer 10 is made of an aluminum material or other suitable metal materials, in order to provide enhanced heat transfer efficiency.

To produce the circuit board structure 1, first dispose the copper foil layer 11, the thermal adhesive layer 12, and the heat radiating layer 10 in a sequence as shown in FIG. 2; apply pressure against the sequentially disposed layers 11, 12, 10, so that the heat radiating layer 10 and the copper foil layer 11 are tightly bonded together via the thermal adhesive layer 12; do subsequent processing, such as drilling, wiring, solder-protection at drilled holes, printing, and surface treatment; and machine the heat radiating layer 10 to form a desired configuration when the general fabricating processes for a circuit board are completed.

Please refer to FIG. 3. When the heat radiating layer 10 and the copper foil layer 11 have been pressed to bond together, the heat radiating layer 10 is machined to form a plurality of erect fins, so that an initially planar heat radiating layer 10 is transformed into a three-dimensional heat radiating layer 10 that has largely increased heat dissipating surface area to enable high efficiency of dissipating heat, so that heat may be efficiently carried away from the circuit board structure 1.

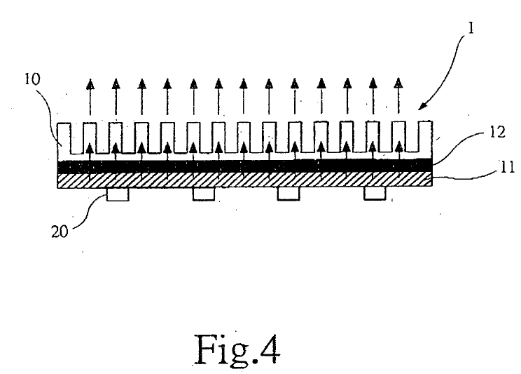

Please refer to FIG. 4. There is a plurality of electronic elements 20 mounted on the circuit board structure 1 according to the first embodiment of the present invention. The electronic elements produce a large amount of heat during operation thereof, and the produced heat is absorbed by the copper foil layer 11 and then transferred to the finned heat radiating layer 10, and finally quickly dissipated from the large surface area of the heat radiating layer 10 into air.

When the planar heat radiating layer 10 has been machined to form a plurality of erect and three-dimensional fins, it provides a largely increased heat dissipating area to enable high dissipating efficiency. Therefore, heat produced by the electronic elements 20 on the circuit board structure 1 and absorbed by the copper foil layer 11 could be transferred to the heat radiating layer 10 and dissipated into air from the three-dimensional fins at a much faster rate.

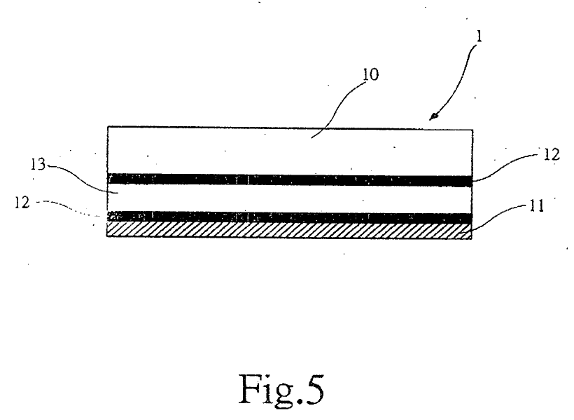

FIG. 5 is a sectioned side view showing a circuit board structure 1 according to a second embodiment of the present invention. In the second embodiment, the circuit board structure 1 includes a heat radiating layer 10 being pressed to bond to an aluminum substrate. The aluminum substrate includes an aluminum sheet 13 and a copper foil layer 11. For the heat radiating layer 10 to tightly bond to the aluminum sheet 13 under pressure, a layer of thermal adhesive 12 is applied between the heat radiating layer 10 and the aluminum sheet 13. Thereafter, do subsequent processing, such as drilling, wiring, solder-protection at drilled holes, printing, and surface treatment; and finally machine the heat radiating layer 10 to form a plurality of erect and three-dimensional fins to provide increased heat dissipating surface area.

Again, in the second embodiment, since the initially planar heat radiating layer 10 is machined to form a plurality of three-dimensional fins to largely increase the heat dissipating surface area thereof, heat may be efficiently carried away from the circuit board structure 1.

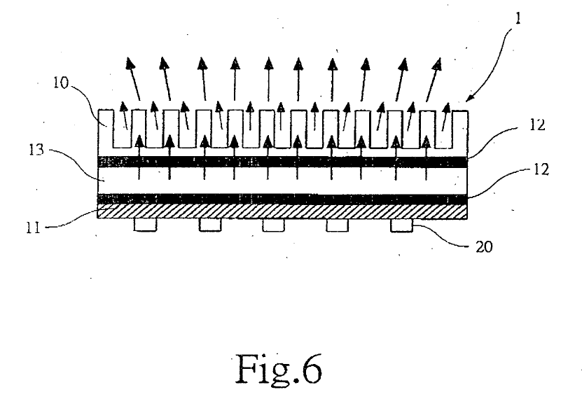

Please refer to FIG. 6. When the electronic elements 20 mounted on the circuit board structure 1 produce heat during operation thereof, the produced heat is absorbed by the copper foil layer 11 and transmitted to the aluminum sheet 13. The heat is then transferred from the aluminum sheet 13 to the finned heat radiating layer 10, which provides increased heat dissipating surface area and high heat absorption capacity to enable further upgraded heat radiation effect.

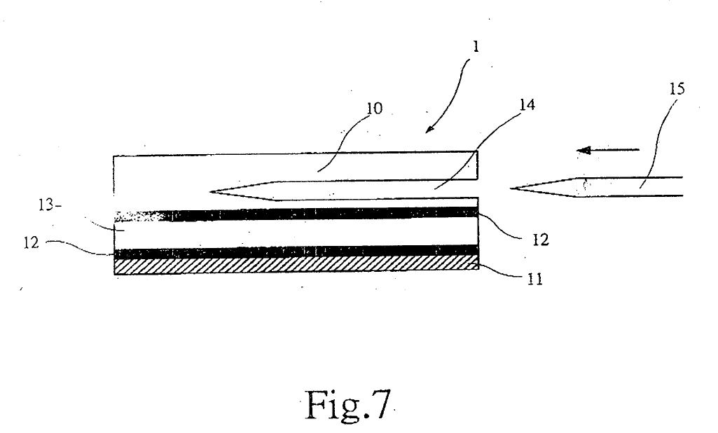

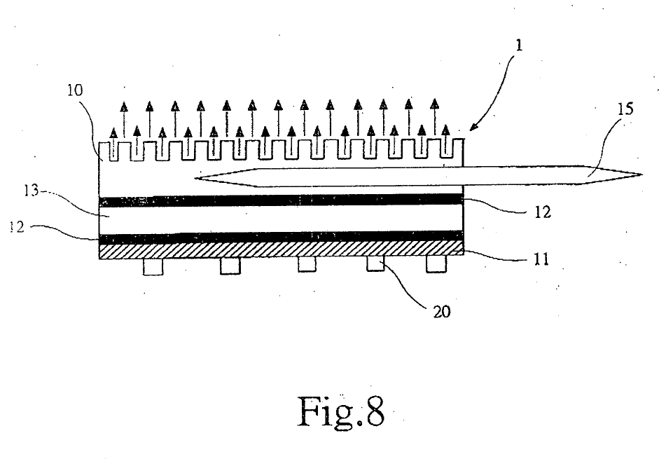

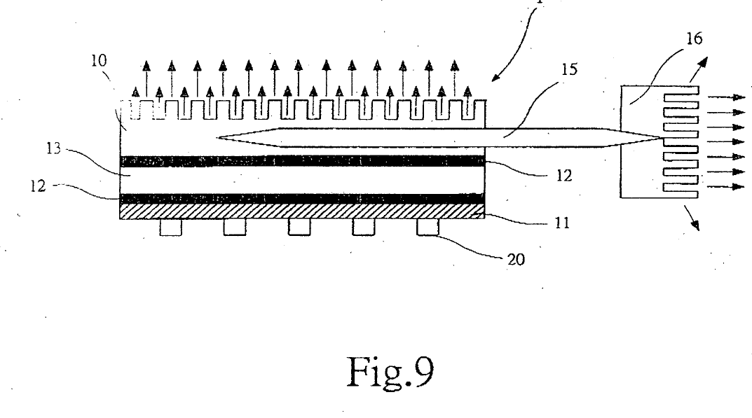

In FIGS. 7 and 8, a circuit board structure 1 according to third embodiment of the present invention is shown. In the third embodiment, an embedding channel 14 is formed in the heat radiating layer 10 and a heat pipe 15 is embedded in the embedding channel 14 before the heat radiating layer 10 is pressed to bond to a circuit board or an aluminum substrate. Thereafter, the heat radiating layer 10 is machined to form a plurality of erect and three-dimensional fins, so that the initially planar heat radiating layer 10 is transformed into a three-dimensional heat radiating layer 10 that has largely increased heat dissipating surface area. In another embodiment of the circuit board structure 1 of FIG. 8, as shown in FIG. 9, a heat radiating mechanism 16 is connected to an outer end of the heat pipe 15, so that heat produced by the electronic elements 20 during operation thereof and transferred to the heat radiating layer 10 is further transferred to the heat radiating mechanism 16 via the heat pipe 15 to enable highly enhanced efficiency of heat radiation.

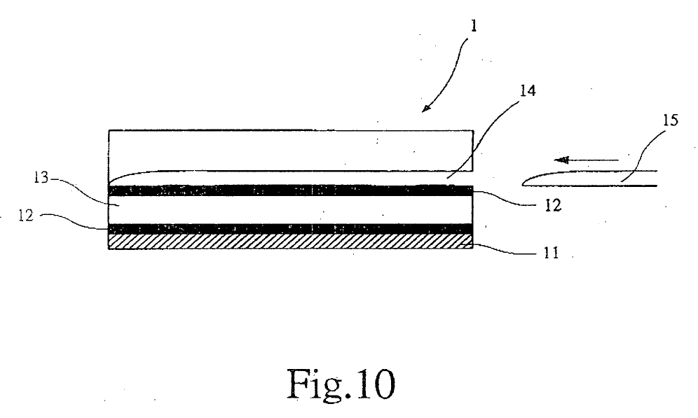

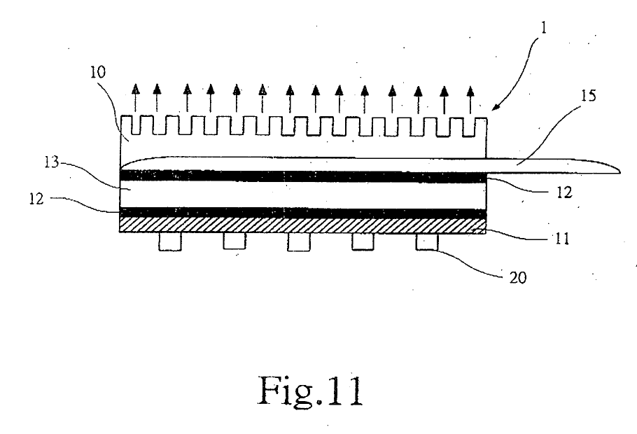

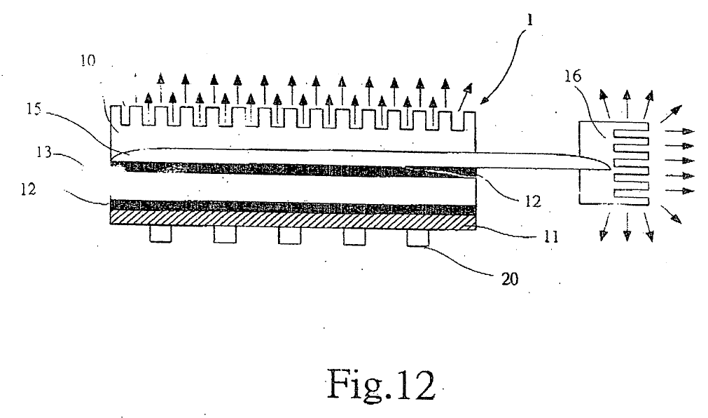

In a fourth embodiment of the present invention as shown in FIGS. 10 and 11, the embedding channel 14 is formed between the heat radiating layer 10 and the thermal adhesive layer 12 for embedding the heat pipe 15. Then, the heat radiating layer 10 is pressed to bond to the circuit board or the aluminum substrate, and machined to form the erect and three-dimensional fins to provide an increased overall heat dissipating surface area and enhanced heat radiating efficiency. In another embodiment of the circuit board structure 1 of FIG. 11, as shown in FIG. 12, a heat radiating mechanism 16 is connected to an outer end of the heat pipe 15, so that heat produced by the electronic elements 20 during operation thereof and transferred to the heat radiating layer 10 is further transferred to the heat radiating mechanism 16 via the heat pipe 15. The three-dimensional fins on the heat radiating layer 10 cooperate with the heat pipe 15 and the heat radiating mechanism 16 to largely improve the efficiency of carrying heat away from the circuit board structure 1, enabling heat produced by the electronic elements 20 to more quickly dissipate into air.

The heat radiating layer 10 may be otherwise directly laminated to a circuit board (not shown). And, the circuit board may be a single-layer or a multilayer circuit board.

By producing the circuit board structure 1 of the present invention in the above described pressing and machining processes, the heat radiating layer 10 is integrally and tightly bonded to the copper foil layer 11 or the aluminum sheet 13 on the aluminum substrate without wasting time and labor to add separate heat radiating sheets to individual electronic elements, and the initially planar heat radiating layer 10 is transformed to a three-dimensional layer with a plurality of erect fins, giving the completed circuit board structure 1 largely increased heat radiating and dissipating surface area and accordingly upgraded heat radiating efficiency.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A circuit board structure with heat radiating layer, comprising a heat radiating layer and a copper foil layer; said circuit board structure being characterized in that a layer of thermal adhesive is applied between said heat radiating layer and said copper foil layer, so that said heat radiating layer is pressed to bond to said copper foil layer via said thermal adhesive layer; and that said heat radiating layer having been pressed to bond to said copper foil layer is machined to form a plurality of erect and three-dimensional fins to provide increased heat dissipating surface area.

2. The circuit board structure with heat radiating layer as claimed in claim 1, wherein said heat radiating layer is made of an aluminum material.

3. The circuit board structure with heat radiating layer as claimed in claim 1, wherein said heat radiating layer is made of a suitable metal material.

4. The circuit board structure with heat radiating layer as claimed in claim 1, wherein said copper foil layer is provided on an aluminum substrate, and said heat radiating layer is pressed to bond to said aluminum substrate.

5. The circuit board structure with heat radiating layer as claimed in claim 4, wherein said aluminum substrate includes an aluminum sheet, on which said copper foil layer is provided; and said layer of thermal adhesive being applied between said heat radiating layer and said aluminum sheet, so that said heat radiating layer is pressed to bond to said aluminum sheet via said thermal adhesive layer before being machined to form said erect and three-dimensional fins.

6. The circuit board structure with heat radiating layer as claimed in claim 1, wherein said heat radiating layer is directly laminated to a circuit board.

7. The circuit board structure with heat radiating layer as claimed in claim 1, wherein said heat radiating layer is internally provided with an embedding channel, in which a heat pipe is embedded.

8. The circuit board structure with heat radiating layer as claimed in claim 1, wherein said heat radiating layer and said copper foil layer are provided there between with an embedding channel, in which a heat pipe is embedded before said heat radiating layer and said copper foil layer are pressed to bond together.

9. The circuit board structure with heat radiating layer as claimed in claim 6, wherein said circuit board is a single-layer circuit board.

10. The circuit board structure with heat radiating layer as claimed in claim 6, wherein said circuit board is a multilayer circuit board.
